(19) United States
(12) Patent Application Publication
(10) Pub. No.: US 2010/0172101 A1
(43) Pub. Date: Jul. 8, 2010

(54) THERMAL INTERFACE MATERIAL AND METHOD FOR MANUFACTURING THE SAME

(75) Inventors: Yuan YAO, Beijing (CN); Shou-Shan FAN, Beijing (CN)

Correspondence Address: PCE INDUSTRY, INC.;ATT. Steven Reiss, 288 SOUTH MAYO AVENUE, CITY OF INDUSTRY, CA, 91789, US

(73) Assignees: TSINGHUA UNIVERSITY, Beijing (CN); HON HAI PRECISION INDUSTRY CO., LTD., Tu-Cheng (TW)

(21) Appl. No.: 12/580,441

(22) Filed: Oct. 16, 2009

(30) Foreign Application Priority Data
Jan. 7, 2009 (CN) 200910104954.6

(51) Int. Cl. H05K 7/20; B32B 9/00; C01B 31/02; B05D 3/10; C23C 16/26

(52) U.S. Cl. 361/704; 428/408; 428/323; 428/328; 427/249.1; 977/742; 977/833; 977/701; 977/843

(57) ABSTRACT

A thermal interface material includes a carbon nanotube array having a plurality of carbon nanotubes, a matrix, and a plurality of heat conductive particles. The carbon nanotube array includes a first end and a second end. The first and second ends are arranged along longitudinal axes of the carbon nanotubes. The matrix is formed on at least one of the first and second ends of the carbon nanotube array. The heat conductive particles are dispersed in the matrix, and the heat conductive particles are thermally coupled to the carbon nanotubes.

### CROSS-REFERENCE TO RELATED APPLICATIONS

This application claims all benefits accruing under 35 U.S.C. §119 from China Patent Application No. 200910104954.6, filed on Jan. 7, 2009 in the China Intellectual Property Office.

### BACKGROUND

1. Technical Field

The present disclosure relates to a thermal interface material based on carbon nanotubes and a method for manufacturing the same.

2. Description of the Related Art

Electronic components such as semiconductor chips are becoming progressively smaller, while at the same time heat dissipation requirements are increasing. Commonly, a thermal interface material is utilized between the electronic component and a heat sink in order to efficiently dissipate heat generated by the electronic component.

A conventional thermal interface material is made by diffusing particles with a high heat conduction coefficient in a base material. The particles can be made of graphite, boron nitride, silicon oxide, alumina, silver, or other metals. However, a heat conduction coefficient of the thermal interface material is now considered to be too low for many contemporary applications, because it cannot adequately meet the heat dissipation requirements of modern electronic components.

A new kind of thermal interface material has recently been developed. The thermal interface material is obtained by fixing carbon fibers with a polymer. The carbon fibers are distributed directionally, and each carbon fiber can provide a heat conduction path. A heat conduction coefficient of this kind of thermal interface material is relatively high. However, the heat conduction coefficient of the thermal interface material is inversely proportional to a thickness thereof, and the thickness is required to be greater than 40 micrometers. In other words, the heat conduction coefficient is limited to a certain value corresponding to a thickness of 40 micrometers. The value of the heat conduction coefficient cannot be increased, because the thickness cannot be reduced.

An article entitled, “Unusually High Thermal Conductivity of Carbon Nanotubes” and authored by Savas Berber (page 4613, Vol. 84, Physical Review Letters 2000) discloses that a heat conduction coefficient of a carbon nanotube can be 6600 W/mK (watts/milliKelvin) at room temperature.

U.S. Pat. No. 6,407,922 discloses another kind of thermal interface material. The thermal interface material is formed by injection molding and has a plurality of carbon nanotubes incorporated in a matrix material. The longitudinal axes of the carbon nanotubes are parallel to the heat conductive direction thereof. A first surface of the thermal interface material engages with an electronic device, and a second surface of the thermal interface material engages with a heat sink. The longitudinal axes of the carbon nanotubes are perpendicular to the first and second surfaces. The second surface has a larger area than the first surface, so that heat can be uniformly spread over the larger second surface.

The first and second surfaces need to be processed to remove matrix material to expose two ends of each of the carbon nanotubes by chemical mechanical polishing or mechanical grinding, thereby improving heat conductive efficiency of the thermal interface material. However, surface planeness of the first and second surfaces can be decreased because of the chemical mechanical polishing or mechanical grinding, which can increase thermal contact resistance between the thermal interface material and the heat source, thereby further decreasing dissipating efficiency. Furthermore, the polishing or grinding process can increase the manufacturing cost.

What is needed, therefore, is a thermal interface material, which can overcome the above-described shortcomings.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of an embodiment of a thermal interface material.

FIG. 2 is a schematic view of a carbon nanotube array used in the thermal interface material of FIG. 1.

FIG. 3 is a schematic, cross-sectional view of an electronic assembly having the thermal interface material of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

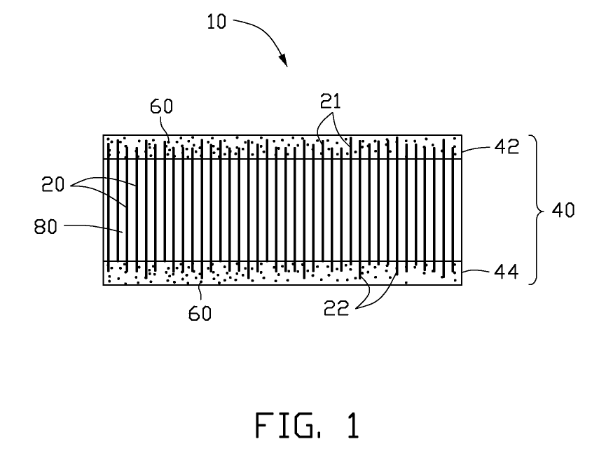

Referring to FIG. 1, one embodiment of a thermal interface material 10 includes a carbon nanotube array 20, a matrix 40, a plurality of heat conductive particles 60, and a polymer 80. The carbon nanotube array 20 includes a plurality of carbon nanotubes. The matrix 40 is formed on at least one end of the carbon nanotube array 20 along longitudinal axes of the carbon nanotubes. The heat conductive particles 60 are uniformly dispersed in the matrix 40 and contact the carbon nanotubes. The polymer 80 is injected in among the carbon nanotubes of the carbon nanotube array 20.

The carbon nanotube array 20 includes a first end 21 and a second end 22 opposite to the first end 21 along the longitudinal axes of the carbon nanotubes. There is no restriction on the height of the carbon nanotube array 20 and its height can be set as desired. The carbon nanotubes of the carbon nanotube array 20 may be single-walled carbon nanotubes, double-walled carbon nanotubes, or multi-walled carbon nanotubes or their combinations. In one embodiment, the carbon nanotubes are multi-walled carbon nanotubes. The carbon nanotube array 20 is a super-aligned carbon nanotube array. The term “super-aligned” means that the carbon nanotubes in the carbon nanotube array 20 are substantially parallel to each other.

The matrix 40 may be formed on one end of the carbon nanotube array 20 or two ends. In one embodiment, the matrix 40 includes a first matrix 42 and a second matrix 44. The first matrix 42 is formed on the first end 21 of the carbon nanotube array 20. The second matrix 44 is formed on the second end 22 of the carbon nanotube array 20. The first and second ends 21, 22 of the carbon nanotubes of the carbon nanotube array 20 are respectively inserted into the first and second matrixes 42, 44. The matrix 40 may be made of phase change material, resin material, heat conductive paste, or the like. The phase change material may be paraffin or the like. The resin material may be epoxy resin, acrylic resin, silicon resin, or the like. In one embodiment, the matrix 40 is made of paraffin. When a temperature of the matrix 40 is higher than the melting point of the matrix 40, the matrix 40 will change to a liquid state.

The heat conductive particles 60 may be made of metal, alloy, oxide, non-metal, or the like. The metal may be tin, copper, indium, lead, antimony, gold, silver, bismuth, aluminum, or any alloy thereof. The oxide may be metal oxide, silicon oxide, or the like. The non-metal particles may be graphite, silicon, or the like. The heat conductive particles 60 may be set as desired to have diameters of about 10 nanometers (nm) to about 10,000 nm. In one embodiment, the heat conductive particles 60 are made of aluminum powder and have diameters of about 10 nm to about 1,000 nm. There is no particular restriction on shapes of the heat conductive particles 60 and may be appropriately selected depending on the purpose.

When the matrix 40 is formed on only one end of the carbon nanotube array 20, the polymer 80 is filled into the remaining portion of the carbon nanotube array 20. When the matrix 40 is formed on the first and second ends 21, 22 of the carbon nanotube array 20, the polymer 80 is filled in between the first and second matrixes 42, 44. In one embodiment, the polymer 80 is filled in between the first and second matrixes 42, 44 as shown in FIG. 1. The polymer 80 may directly contact the first and second matrixes 42, 44 or be spaced from the first and second matrixes 42, 44. The polymer 80 may be made of silica, polyethylene glycol, polyester, epoxy resin, anaerobic adhesive, acryl adhesive, rubber, or the like. Understandably, the polymer 80 can be made of the same material as the matrix 40. In one embodiment, the polymer 80 is directly contacting the first and second matrixes 42, 44 and made of two-component silicone elastomer.

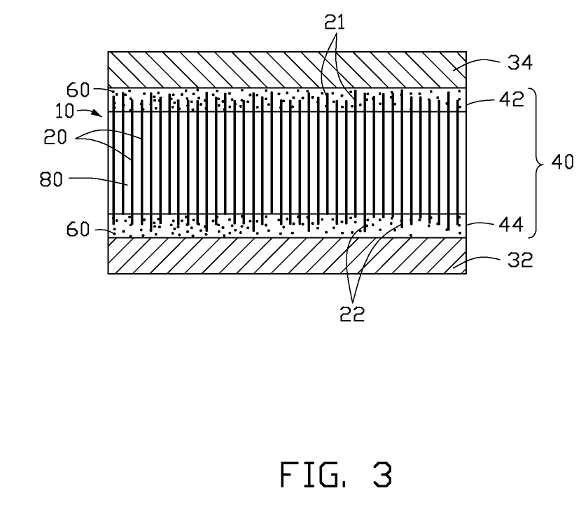

Referring to FIG. 3, the thermal interface material 10 is applied between a first element 32, such as an electronic component, and a second element 34 such as a heat sink. The thermal interface material 10 is heated up by the heat generated by the electronic component. When the temperature of the matrix 40 is higher than its melting point, the matrix 40 changes to a liquid state, and along with the heat conductive particles 60, flow and fill the contact surface of the first element 32 and the second element 34 that has low surface planeness, thereby increasing the actual contact area between the thermal interface material 10 and the first element 32 and between the thermal interface material 10 and the second element 30. Thus, thermal contact resistance between the thermal interface material 10 and the first element 32, and between the thermal interface material 10 and the second element 34 are decreased. Furthermore, the heat conductive particles 60 directly contact the carbon nanotubes of the carbon nanotube array 20, thereby increasing heat dissipating efficiency. The heat conductive particles 60 flow inwards into intervals defined between every adjacent two carbon nanotubes of the carbon nanotube array 20 filling in any space between the first element 32 and the second element 30. Thus, the heat dissipating efficiency of the thermal interface material can be further increased.

Depending on the embodiment, certain of the steps described in the methods below may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

One embodiment of a method for fabricating the thermal interface material is shown. The method includes:

step S10: providing the carbon nanotube array 20;

step S11: forming the matrix 40 on the first and second ends 21, 22 of the carbon nanotube array 20; and

step S12: adding a plurality of heat conductive particles 60 into the matrix 40 and contacting the heat conductive particles 60 with the carbon nanotubes of the carbon nanotube array 20 to obtain the thermal interface material 10.

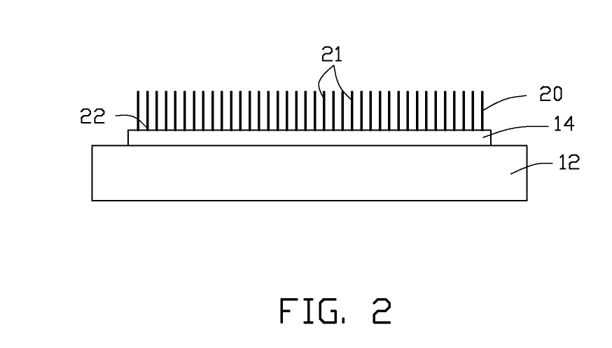

In step S10, the carbon nanotube array 20 may be acquired by the following method. The method employed may include, but not limited to, chemical vapor deposition (CVD), Arc-Evaporation Method, or Laser Ablation. In one embodiment, the method employs high temperature CVD. Referring to FIG. 2, the method includes:

step S101: providing a substrate 12;

step S102: forming a catalyst film 14 on the surface of the substrate 12;

step S103: treating the catalyst film 14 by post oxidation annealing to change it into nano-scale catalyst particles;

step S104: placing the substrate 12 having catalyst particles into a reaction chamber; and

step S105: adding a mixture of a carbon source and a carrier gas for growing the carbon nanotube array 20.

In step S101, the substrate 12 may be a glass plate, a multiporous silicon plate, a silicon wafer, or a silicon wafer coated with a silicon oxide film on the surface thereof. In one embodiment, the substrate 12 is a multiporous silicon plate, that is, the plate has a plurality of pores with diameters of less than 3 nm.

In step S102, the catalyst film 14 may have a thickness in a range from about 1 nm to about 900 nm and the catalyst material may be Fe, Co, Ni, or the like.

In step S103, the treatment is carried out at temperatures ranging form about 500° C. to about 700° C. from about 5 hours to about 15 hours.

In step S104, the reaction chamber is heated up to about 500° C. to about 700° C. and filled with protective gas, such as inert gas or nitrogen for maintaining purity of the carbon nanotube array 20.

In step S105, the carbon source may be selected from acetylene, ethylene or the like, and have a velocity of about 20 standard cubic centimeters per minute (sccm) to about 50 sccm. The carrier gas may be inert gas or nitrogen, and have a velocity of about 200 sccm to about 500 sccm.

In step S11, as described above, the matrix 40 includes the first matrix 42 and the second matrix 44. The first and second matrixes 42, 44 are respectively formed on the first and second ends 21, 22 of the carbon nanotube array 20. The method of forming the first and second matrixes 42, 44 is described in the following. The method includes:

step S110: injecting the polymer 80 among the carbon nanotubes of medium portion of the carbon nanotube array 20;

step S111: coating the first matrix 42 on the exposed first end 21 of the carbon nanotube array 20;

step S112: removing the substrate 12 connected to the second end 22 of the carbon nanotube array 20; and

step S113: coating the second matrix 44 on the second end 22 of the carbon nanotube array 20.

In step S110, a method of injecting the polymer 80 among the carbon nanotubes includes the following steps:

forming a protective layer on the first end 21 of the carbon nanotube array 20;

immersing the carbon nanotube array 20 having the protective layer into a solution of the polymer 80;

curing the liquid state based polymer 80 filled in interstices between the carbon nanotubes to form a composite material of the polymer 80 and the carbon nanotube array 20; and

removing the protective layer from the composite material.

The protective layer may be made of polyresin or the like. The protective layer can be directly pressed on the end of the carbon nanotube array 20 to tightly contact with it. The liquid state based polymer 80 is placed in the air or stove to cure and dry it or is placed into a cool room to dry it. Understandably, if a height of the carbon nanotube array 20 immersed by the solution of the polymer 80 can be predetermined as desired, the protective layer can be omitted.

In step S111, the first matrix 42 can be coated on the first end 21 of the carbon nanotube array 20 via a brush or printed on that end via a printer. In step S112, the substrate 12 can be directly striped or etched via chemical etch method. In step S113, a method of coating the second matrix 44 may be similar to that of coating the first matrix 42. Understandably, when only the first end 21 of the carbon nanotube array 20 is coated with the first matrix 42, the step S113 can be omitted.

In step S12, a method of adding the heat conductive particles 60 includes distributing a number of the heat conductive particles 60 on a surface of the first matrix 42 and heating the first matrix 42 to a temperature higher than the melting point of the first matrix 42. When the temperature of the first matrix 42 is higher than the melting point thereof, the first matrix 42 will change to a liquid state. The liquid-state first matrix 42 may not easily flow because of surface tension. The heat conductive particles 60 can fall into the liquid-state first matrix 42 due to gravity. Understandably, the method of adding the heat conductive particles 60 into the second matrix 44 is similar to that as described above. There is no particular restriction on the quantity of the heat conductive particles 60 as long as the heat conductive particles 60 can thermally connect to the carbon nanotubes of the carbon nanotube array 20.

Understandably, in step S11, the matrix 40 can be formed on one of the first and second ends 21, 22 of the carbon nanotube array 20.

In the above method of fabricating the thermal interface material, a good conductive channel is formed between the thermal interface material because of the heat conductive particles and the carbon nanotubes. In order to decrease the thermal contact resistance between the thermal interface material and the electronic components, the surface of the thermal interface material does need not to be treated, such as through chemical mechanical polishing or mechanical grinding, because the matrix can be melted into a liquid state. Therefore, the manufacture cost can be decreased.

It is to be understood, however, that even though numerous characteristics and advantages of embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A thermal interface material, comprising:
a carbon nanotube array comprising a plurality of carbon nanotubes, the carbon nanotube array having a first end and a second end, the first and second ends being arranged along longitudinal axes of the carbon nanotubes;
a matrix formed on at least one of the first and second ends of the carbon nanotube array; and
a plurality of heat conductive particles dispersed in the matrix, the heat conductive particles thermally coupled to the carbon nanotubes.

2. The thermal interface material of claim 1, wherein the matrix is formed on both the first and second ends of the carbon nanotube array, the matrix comprises a first matrix and a second matrix, the first matrix is formed on the first end of the carbon nanotube array, the second matrix is formed on the second end of the carbon nanotube array.

3. The thermal interface material of claim 1, wherein the heat conductive particles have a diameter of about 10 nanometers to about 10,000 nanometers.

4. The thermal interface material of claim 1, wherein the heat conductive particles are made of metal, alloy, oxide, non-metal, or their combinations.

5. The thermal interface material of claim 4, wherein the metal is selected from the group consisting of tin, copper, indium, lead, antimony, gold, silver, bismuth, and aluminum.

6. The thermal interface material of claim 4, wherein the alloy is made of materials selected from the group consisting of tin, copper, indium, lead, antimony, gold, silver, bismuth, and aluminum.

7. The thermal interface material of claim 1, wherein the matrix is made of phase change material, resin material, or heat conductive paste.

8. The thermal interface material of claim 7, wherein the phase change material comprises paraffin.

9. The thermal interface material of claim 7, wherein the resin material is selected from the group consisting of epoxy resin, acrylic resin, and silicon resin.

10. The thermal interface material of claim 1, further comprising a polymer positioned among the carbon nanotubes of the carbon nanotube array.

11. The thermal interface material of claim 10, wherein the polymer is made of silica, polyethylene glycol, polyester, epoxy resin, anaerobic adhesive, acryl adhesive, or rubber.

12. The thermal interface material of claim 10, wherein the polymer and the matrix are made of a same material.

13. A method of fabricating a thermal interface material, the method comprising:
providing a carbon nanotube array comprising a plurality of carbon nanotubes, the carbon nanotube array having a first end and a second end, the first and second ends are arranged along longitudinal axes of the carbon nanotubes;
forming a matrix on at least one of the first and second ends of the carbon nanotube array; and
adding a plurality of heat conductive particles into the matrix, the heat conductive particles contacting the carbon nanotubes of the carbon nanotube array to obtain the thermal interface material.

14. The method of claim 13, wherein the method of fabricating the carbon nanotube array comprises:
providing a substrate;
forming a catalyst film on the surface of the substrate;
treating the catalyst film by post oxidation annealing to change the catalyst film into nano-scale catalyst particles;
placing the substrate with the catalyst particles into a reaction chamber; and
adding a mixture of a carbon source and a carrier gas for growing the carbon nanotube array.

15. The method of claim 13, further comprising a step of injecting a polymer among the carbon nanotubes of the carbon nanotube array before forming a matrix on the at least one of the first and second ends of the carbon nanotube array.

16. The method of claim 15, wherein a method of injecting the polymer among the carbon nanotubes, comprises:
forming a protective layer on the exposed end of the carbon nanotube array;
immersing the carbon nanotube array having the protective layer into a solution of the polymer;
curing the liquid-state polymer filled in clearances among the carbon nanotubes to form a composite material of the polymer and the carbon nanotube array; and
removing the protective layer from the composite material.

17. The method of claim 13, wherein a method of adding the heat conductive particles into the matrix, comprises:
distributing a number of the heat conductive particles on a surface of the matrix; and
heating the matrix to a temperature higher than the melting point of the matrix.

18. An electronic assembly, comprising:
a first element generating heat during operation;
a second element configured for transferring heat away generated by the first element; and
a thermal interface material applied between the first element and the second element, the thermal interface material comprising:
a carbon nanotube array comprising a plurality of carbon nanotubes and an interval defined between every adjacent two carbon nanotubes;
a matrix formed on at least one end of the carbon nanotube array along longitudinal axes of the carbon nanotubes; and
a plurality of heat conductive particles dispersed in the matrix and driven to move in the intervals by the heat generated by the first element.

19. The electronic assembly of claim 18, further comprising a polymer located among the carbon nanotubes of the carbon nanotube array, wherein the heat conductive particles move in the polymer between the intervals when a temperature of the thermal interface material is higher than the melting point thereof.

20. The electronic assembly of claim 18, wherein the heat conductive particles are thermally coupled to the carbon nanotubes.
